(19) United States
(12) Patent Application Publication
(10) Pub. No.: US 2025/0089336 A1
(43) Pub. Date: Mar. 13, 2025

(54) DUAL SIDED CIRCUIT CONNECTIONS

(71) Applicant: International Business Machines Corporation, Armonk, NY (US)

(72) Inventors: Brent A. Anderson, Jericho, VT (US); Albert M. Chu, Nashua, NH (US); Junli Wang, Slingerlands, NY (US); Ruilong Xie, Niskayuna, NY (US); Jay William Strane, Wappingers Falls, NY (US)

(21) Appl. No.: 18/464,369

(22) Filed: Sep. 11, 2023

(51) Int. Cl. H01L 29/417; H01L 23/528; H01L 27/088; H01L 29/06; H01L 29/423; H01L 29/66; H01L 29/775; H01L 29/786

(52) U.S. Cl. CPC H10D 64/258; H01L 23/5286; H10D 30/014; H10D 30/43; H10D 30/6735; H10D 30/6757; H10D 62/121; H10D 64/017; H10D 84/83

(57) ABSTRACT

A semiconductor device includes a top side and a bottom side opposite the top side. A central portion including a semiconductor substrate is disposed between the top side and the bottom side. A component is disposed in the central portion in contact with the semiconductor substrate. The component includes a first electrical connection from the top side and a second electrical connection from the bottom side.

### BACKGROUND

The present invention generally relates to semiconductor devices and processing methods, and more particularly to semiconductor devices having front and backside wiring for dual sided connections that contact devices or device components from opposing sides.

Integrated circuit devices are constructed by forming diffusion regions in a substrate and then building up wiring connections from the substrate through to a back end of line (BEOL) structure. Such devices present a diffusion region (e.g., source/drain region) on one side of the device formed in the substrate, and a contact is dropped down to connect with the diffusion region. Metal lines connect to the contacts and are themselves connected to by other contacts and metal lines to form a metal structure in accordance with a chip design. In the case of a stacked field effect transistor structure where field effect transistors are stacked one on the other, the device is again built up from the substrate. Even flipping the wafer or substrate to process the opposite side, contacts are dropped toward the substrate.

In devices where a large-stacked gate structure is employed, e.g., in a nanosheet stack, gate resistance limits the switching capabilities of a transistor controlled by the gate because of the large size of the gate, e.g., the large distance between a top and bottom of the gate. Since contact is made to the top of the large gate structure, the distant bottom of the gate introduces gate resistance.

Asymmetry of the metal structure about a substrate can lead to parasitic resistance and wire resistance across the chip or device.

Therefore, a need exists for a more balanced wiring arrangement to address gate resistance issues, area constraints and parasitic losses in integrated circuits. A further need exists for making multiple connections to a same component to reduce contact resistance and current density through connective metal structures.

### SUMMARY

In accordance with an embodiment of the present invention, a semiconductor device includes a top side and a bottom side opposite the top side. A central portion includes a semiconductor substrate disposed between the top side and the bottom side. A component disposed in the central portion is in contact with the semiconductor substrate. The component includes a first electrical connection from the top side and a second electrical connection from the bottom side. With the use of a first and second electrical connection to the components, resistances due to in adequate connection surface area are alleviated. Such issues, such as gate resistance or contact resistance are greatly reduced as a result of using dual connections. Further, the use of another wiring side in accordance with embodiments of the present invention, opens up many possibilities in terms circuit layouts, conserving areal space and reducing current density through electrical connections.

In accordance with another embodiment of the present invention, a semiconductor device includes top side wiring including metal lines and contacts and bottom side wiring including metal lines and contacts and disposed opposite the top side wiring. A central portion includes a semiconductor substrate disposed between the top side wiring and the bottom side wiring. A component is formed on the semiconductor substrate and is disposed in the central portion. The component includes a first electrical connection from the top side wiring and a second electrical connection from the bottom side wiring. The first and second electrical connections can reduce resistances due to inadequate connection surface area. With resistance greatly reduced, device performance is improved. Further, the use of another wiring side in accordance with embodiments of the present invention, opens up many possibilities in terms circuit layouts, conserving areal space and reducing current density through electrical connections.

In accordance with another embodiment of the present invention, a semiconductor device includes top side wiring including metal lines and contacts and bottom side wiring including metal lines and contacts and disposed opposite the top side wiring. A central portion includes a semiconductor substrate disposed between the top side wiring and the bottom side wiring. A first component is formed on the semiconductor substrate and is disposed in the central portion. The first component includes a first electrical connection from the top side wiring and a second electrical connection from the bottom side wiring. A second component is formed on the semiconductor substrate and disposed in the central portion. The second component includes a first electrical connection from the top side wiring and a second electrical connection from the bottom side wiring. In addition to reducing resistances, a bridge connects the first electrical connection of the first component to the first electrical connection of the second component. By connecting subcircuits across the device using a bridge, the top and bottom metal structures can be employed in a single circuit that spans the top, bottom and central region of the device.

In accordance with another embodiment of the present invention, a semiconductor device, includes top side wiring including metal lines and contacts and bottom side wiring including metal lines and contacts and disposed opposite the top side wiring. A central portion includes a semiconductor substrate disposed between the top side wiring and the bottom side wiring. A first circuit is disposed in the top side wiring and the bottom side wiring. The first circuit has a first component including a first electrical connection from the top side wiring and a second electrical connection from the bottom side wiring. A second circuit is disposed in the top side wiring and the bottom side wiring. The second circuit includes a second component having a first electrical connection from the top side wiring and a second electrical connection from the bottom side wiring. A bridge connects the first circuit to the second circuit to form a single circuit across the top side wiring, bottom side wiring and the central portion, wherein the top side wiring mirrors the bottom side wiring relative to the central portion. In addition to reducing resistances, a bridge connects the first electrical connection of the first component to the first electrical connection of the second component. By connecting subcircuits across the device using a bridge, the top and bottom metal structures can be employed in a single circuit that spans the top, bottom and central region of the device.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a schematic cross-sectional view of a semiconductor device having a central portion with a substrate and including metal structures in a top side and metal structures in a bottom side where the metal structures in the top side and the bottom side provide dual connections to components and the metal structures in the top side and the bottom side mirror each other in one or more dimensions, in accordance with an embodiment of the present invention;

FIG. 2 shows a schematic cross-sectional view of a semiconductor device having a central portion with a substrate and including metal structures in a top side and metal structures in a bottom side where the metal structures in the top side and the bottom side provide dual connections and have a similar metal density but do not exactly mirror each other, in accordance with an embodiment of the present invention;

FIG. 3 shows a top layout view of a semiconductor device where the semiconductor device includes metal structures in a top side and metal structures in a bottom side where the metal structures in the top side and the bottom side provide dual connections and mirror each other in one or more dimensions, in accordance with an embodiment of the present invention;

FIG. 4 shows three schematic cross-sectional views taken at section lines A, B and E of FIG. 3 depicting a semiconductor device where the semiconductor device includes metal structures in a top side and metal structures in a bottom side where the metal structures in the top side and the bottom side provide dual connections and mirror each other in one or more dimensions, in accordance with an embodiment of the present invention;

FIG. 5 shows a top layout view of a semiconductor device where the semiconductor device includes metal structures in a top side and metal structures in a bottom side where the metal structures in the top side and the bottom side provide dual connections but do not mirror each other and include through contacts that traverse a semiconductor substrate, in accordance with an embodiment of the present invention;

FIG. 6 shows three schematic cross-sectional views taken at section lines C, D and F of FIG. 5 depicting a semiconductor device where the semiconductor device includes metal structures in a top side and metal structures in a bottom side where the metal structures in the top side and the bottom side provide dual connections but do not mirror each other and include through contacts that traverse a semiconductor substrate, in accordance with an embodiment of the present invention;

FIG. 7 shows a schematic cross-sectional view of a semiconductor device having a central portion with a substrate and a nanosheet stack gate structure having duel connections that are also connected by a through contact that traverses the substrate in to reduce gate resistance, in accordance with an embodiment of the present invention;

FIG. 8 shows a schematic cross-sectional view of a semiconductor device having a central portion with a substrate and a nanosheet stack gate structure and an active region connected across different circuits having duel connections, in accordance with an embodiment of the present invention;

FIG. 9 shows a schematic cross-sectional view of a semiconductor device having a central portion with a substrate and a nanosheet stack gate structure and an active region connected across different circuits by a bridge and having duel connections also connected by through contacts, in accordance with an embodiment of the present invention; and

FIG. 10 shows a schematic cross-sectional view of a semiconductor device having a central portion with a substrate and a nanosheet stack gate structure and stacked field effect transistors connected across different circuits by a bridge and having duel connections also connected by through contacts, in accordance with an embodiment of the present invention.

### DETAILED DESCRIPTION

In accordance with embodiments of the present invention, devices and methods are described which include semiconductor devices with frontside and backside wiring to permit duel connections to a single component. The duel connection can include a connection from a top wiring circuit and a connection from a bottom wiring circuit. The top and bottom wiring circuits are separated by a semiconductor substrate. Connections can be made between the dual connections, e.g., using a through contact. The duel connections can be controlled to concurrently activate the component from the top and bottom wiring circuits. In other embodiments, the top and bottom wiring circuits can be employed independently to power or derive a signal from the component.

The duel connections are formed within metal layers or structures of the semiconductor device, and are formed on and provide access to components through opposite sides of the semiconductor device. The metal layers or structures provide completely separate connections to a same components. In this way, current density can be reduced by employing completely different circuit paths to a common components of the semiconductor device (e.g., gate, source region, drain region, etc.)

In one embodiment, an electrical connection can be made between two device elements with both frontside and backside connections to a same device element. In one example, a source/drain (S/D) region can be connected from both a front side and a backside of the device. In another example, a gate region can be connected from both a front side and a backside of the device.

In useful embodiments, a first wire connection can be made to a component (e.g., to a S/D top) and a second wire connection can be made to the same component (S/D bottom) and a third wire connection (e.g., a through contact formed through the semiconductor substrate) can be made between the first and second wire connections. This can include a number of different configurations. For example, the wire connections can be joined on one side or the other or the connection can pass through a substrate of a chip on which the component is formed.

In another embodiment, the component can include a gate wherein the first wire connection can be made, e.g., to a gate top and the second wire connection can be made to the same component (e.g., gate bottom) and the third wire connection can be made between the first and second wire connections.

In still other embodiments, a first wire connection can be made to first and second S/D tops and second and third wire connections can be made to first and second S/D bottoms, respectively, and to the first wire. In one embodiment, a first top and bottom connection can be made to a first device S/D, and a second top and bottom connection can be made to a gate of a second device. One or more electrical connections can be made between the first and second devices.

With top side and bottom side wiring circuits, a more symmetrical power or signal structure is achieved. The top side and bottom side circuits can include mirror images of one another, or the top side and bottom side circuits can include different layouts. Even with different layouts, a similar metal density can be employed to provide a more uniform voltage field across the device. In either case, the top side and bottom side circuits provide greater electrical symmetry and parallelism for the device.

By having back side metal in parallel with front side metal, circuit performance can be improved by reducing wire resistance and parasitic resistance. Further, the additional backside metal also improves electro-migration resistance by reducing current density through the electrical connections. For example, two connections instead of one reduces the current density by about half. This is particularly pronounced in small node devices where the sizes of features are nanoscale in magnitude.

When employed in conjunction with gate structures, the top side and bottom side wiring improves device electro-statics for thicker nanosheet (NS) stacks, especially for stacks with, e.g., 3 or more sheets, by contacting the gate from both sides. In this way, a voltage drop across the gate structure due to gate resistance is minimized.

Embodiments of the present invention can be employed in any type of semiconductor device or chip. In particularly useful embodiments, chips with logic circuitry can include dual connections in accordance with embodiments of the present invention. For example, the present embodiments can include input/output (IO) circuits, high performance computing (HPC) circuits, clock buffers, processors, memory devices or any other integrated circuit chip or combinations thereof. By sandwiching a central portion of a device with top side and bottom side metal in parallel, circuit performance can be improved for any of these devices by reducing wire and parasitic resistance. In addition, adding an additional metal on an opposite side of a device can be integrated into any fabrication process with little or no impact on expense or processing time.

In useful embodiments, the top side and bottom side metal is evenly distributed to disperse current density. In particularly useful embodiments, the front side metal structure mirrors the backside metal structure. The mirror image can include one dimensional, two dimensional or three dimensional symmetry between top side and bottom side metal structures relative ta center plane (or central region) of the device. In this way, a deliberate effort is made to form contacts and metal lines that correspond on opposite sides of the device. This can include the same widths, lengths and footprints, connection points, distances, etc. for metal structures on opposite sides of the device.

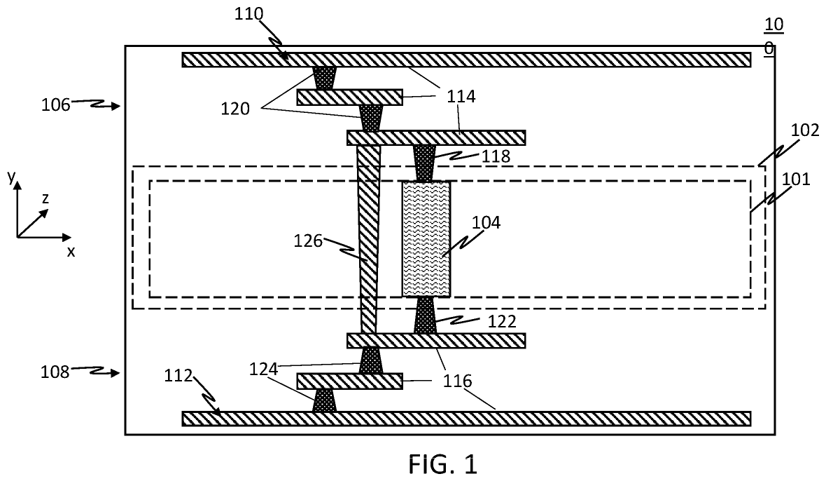

Referring now to the drawings in which like-numerals represent the same or similar elements and initially to FIG. 1, a schematic cross-sectional view of a semiconductor device 100 is shown in accordance with an embodiment of the present invention. The semiconductor device 100 includes a central region 102. The central region 102 can include front end of line (FEOL) structures and can also include middle of the line (MOL) structures. The central region 102 can include a substrate 101 having semiconductor components 104 formed therein and/or thereon.

The substrate 101 can include any suitable substrate structure, e.g., a bulk semiconductor, a semiconductor-on-insulator (SOI) substrate, etc., and preferably includes a monocrystalline semiconductor. In one example, the substrate 101 can include a silicon-containing material. Illustrative examples of Si-containing materials suitable for the substrate can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

Semiconductor components 104 can include, e.g., active regions, such as source/drain regions (S/D regions), gate structures, capacitor plates, memory elements, etc. Other components can include other electronic and electrical components. A contact connecting to a component as described throughout provides a physical and electrical connection thereto. Duel connections provide at least two contacts to a component, where each of the duel connections is associated with wiring on an opposite side of the device. The semiconductor components 104 with duel connections are formed on or in the substrate 101 in the central region 102.

In one embodiment, the central region 102 is sandwiched between a top side 106 and a bottom side 108 of the semiconductor device 100. The metal structure of the top side 106 and the metal structure of the bottom side 108, in this embodiment, are mirror images of each other. For example, metal lines 114 and contacts 118, 120 of the top side 106 provide symmetry or a mirror image with the metal lines 116 and contacts 122, 124 of the bottom side 108. Metal structures of the top side 106 will be collectively referred to as top side wiring 110, and metal structures of the bottom side 108 will be collectively referred to as bottom side wiring 112. The symmetry or mirror image provided between top side wiring 110 and bottom side wiring 112 can extend to one or more dimensions. For example, top side wiring 110 can be symmetrical to the bottom side wiring 112 in any or all of the x, y and/or z directions, where two of these directions define a plane of the substrate 101.

The symmetry between the top side wiring 110 and the bottom side wiring 112 is provided to reduce asymmetry in overall electrical characteristics of the semiconductor device 100. For example, the symmetry provides two paths for circuit current flow. Half of the current flows through the top side wiring 110 while the other half flows through the bottom side wiring 112. By reducing the amount of the current flowing through each wire, this implementation avoids high current which can cause electro-migration failures.

In addition, parasitic and wire resistances can be reduced or better controlled in accordance with the top side wiring 110 and bottom side wiring 112 characteristics. It should be understood that exact symmetry is not needed and that the degree of symmetry can vary based upon the performance goals of a particular design.

The central region 102 includes dual sided circuit connections (duel connection) from both the top side wiring 110 and the bottom side wiring 112. A contact 118 connects to the components 104 from the top side 106 and a contact 122 connects to the components 104 from the bottom side wiring 112. The contacts 118 and 122 may be positioned in a same vertical column relative to one another and contact the component from opposite sides. The top side wiring 110 and the bottom side wiring 112 can provide power or signal connections to the components 104.

It should be understood that the top side wiring 110 and the bottom side wiring 112 can be built outward from the central region 102 by building one side and then flipping the semiconductor device to build the other side. In other embodiments, the build may be unidirectional from the bottom side 108 to top side 106 or vice versa. The top side wiring 110 and the bottom side wiring 112 are in electrical communication with one another. The dual connections can act together to provide concurrent power or signal to a single component(s) from opposing sides of the device. The dual connections can also act independently of one another, e.g., power the component from one side under a first condition (e.g., activating a first circuit) and power the component from both sides in a second condition (e.g., activating a second circuit where the component is common to both circuits).

In some embodiments, it may be useful to have connections 126 between the top side wiring 110 and the bottom side wiring 112. Connection(s) 126 can include a through contact that traverses the central region 102, e.g., connects to or through a substrate of the semiconductor device 100. Connection 126 can be formed from one side or may be formed from the top side 106 and the bottom side 108 to meet within the central region 102.

In one embodiment, an etch mask is formed on either the top side or the bottom side and etched through the substrate 101 (and any other intervening structures) to open up a trench. The hole or trench can then be filled with an optional barrier layer and a conductor to form the connection 126. In some embodiments, the connection 126 can include a sequence of connections or a stack of connections. It should be understood that the electrical connections shown in FIG. 1 and the other FIGS. are illustrative and that other connections, wiring configurations and connections points are contemplated in accordance with embodiments of the present invention.

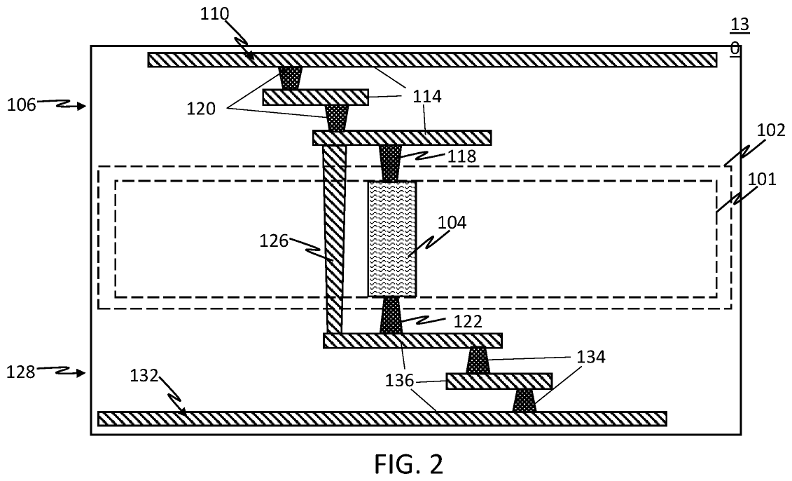

Referring to FIG. 2, a schematic cross-sectional view of a semiconductor device 130 is shown in accordance with an embodiment of the present invention. The semiconductor device 130 includes a central region 102. The central region 102 can include front end of line (FEOL) structures and can also include middle of the line (MOL) structures. The central region 102 can include a substrate 101 having semiconductor components 104 formed therein and/or thereon.

Semiconductor components 104 can include, e.g., active regions, such as source/drain regions (S/D regions), gate structures, capacitor plates, memory elements, etc. Other components can include other electronic and electrical components.

In one embodiment, the central region 102 is sandwiched between the top side 106 and a bottom side 128 of the semiconductor device 130. The top side 106 and the bottom side 128 in this embodiment do not include symmetrical structures, but provide a similar metal structure to distribute conductive materials between the top side 106 and the bottom side 128 evenly, based on metal or conductor density (e.g., conductor mass per unit volume). In one example, conductor density is maintained within about 10% between the top side 106 and a bottom side 128 metal structures.

In one example, metal lines 114 and contacts 118, 120 of the top side 106 provide similar amounts of metal with the metal lines 136 and contacts 122, 134 of the bottom side 138. Metal structures of the top side 106 will be collectively referred to as top side wiring 110, and metal structures of the bottom side 128 will be collectively referred to as bottom side wiring 132. Greater uniformity of current density across the semiconductor device 100 can still be achieved to assist in controlling the effects of electro-migration, parasitic resistances and wire resistances in accordance with the top side wiring 110 and bottom side wiring 132 characteristics.

The central region 102 includes dual sided circuit connections from both the top side wiring 110 and the bottom side wiring 132. A contact 118 connects to the components 104 from the top side 106, and a contact 122 connects to the components 104 from the bottom side 138. The contacts 118 and 122 may be positioned in a same vertical column relative to one another and contact the component from opposite sides. The top side wiring 110 and the bottom side wiring 132 can provide power or signal connections to the components 104.

It should be understood that the top side wiring 110 and the bottom side wiring 132 can be built outward from the central region 102 by building one side and then flipping the semiconductor device to build the other side. In other embodiments, the build may be unilaterally from the bottom side 128 to top side 106 or vice versa.

In some embodiments, it may be useful to have connections 126 between the top side wiring 110 and the bottom side wiring 132. Connection(s) 126 can include a through contact that traverses the central region 102, e.g., connects to or through a substrate of the semiconductor device 130. Connection 126 can be formed from one side or may be formed from the top side 106 and the bottom side 128 to meet within the central region 102. It should be understood that the electrical connections shown in FIG. 2 and the other FIGS. are illustrative and that other connections, wiring configurations and connections points are contemplated in accordance with embodiments of the present invention.

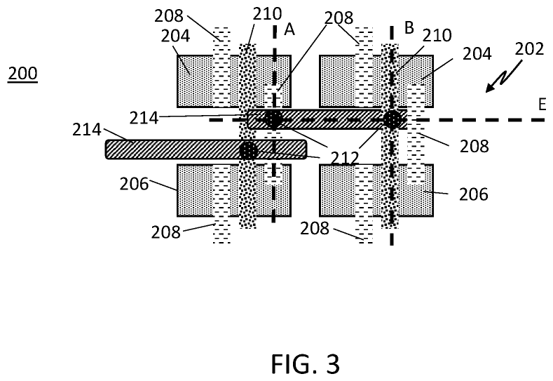

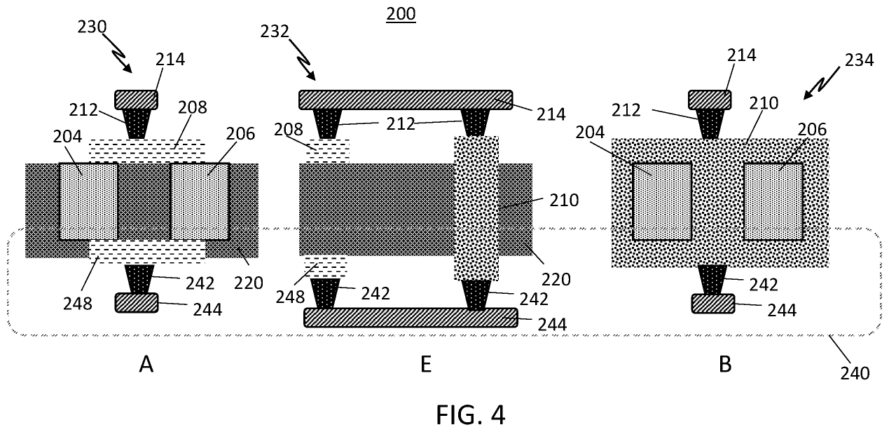

Referring to FIGS. 3 and 4, a top layout view 202 and three partial schematic cross-sectional views 230, 232, 234 are shown for a semiconductor device 200 having dual connections in accordance with embodiments of the present invention. Dielectric materials and layers are omitted to permit viewing of underlying metal structures. The top view 202 shows active regions 204 and 206. In one embodiment, the active regions 204 include p-doped regions and the active regions 206 include n-doped regions. This can be reversed or all regions can be n-doped or p-doped. The active regions 204 and 206 provide S/D regions for transistor devices, such as field effect transistors (FETs) as well as channels between the S/D regions. The channels for the devices are located below gate conductors 210. The gate conductors 210 are connected to metal lines 214 through contacts 212. The active regions 204, 206 are connected, where appropriate by metal lines 208. Contacts 212 connect the metal lines 208 to the metal lines 214.

Shallow trench isolation (STI) regions 220 are depicted in the partial cross-sectional views 230, 232 and 234. View 230 is taken through section line A, view 232 is taken through section line E and view 234 is taken through section line B as shown in top view 202. Region 240 shows mirror image metal structures formed to provide dual contact connections. Duel connections are made in view 230 to and between the active regions 204 and 206 by a contact 212 above and a contact 242 below the active regions 204 and 206. Metal lines 244 and 248 in region 240 correspond in a mirror image relationship with corresponding metal lines 214 and 208. Likewise the contacts 212 and 242 make duel connections from opposing positions relative to the active regions 204 and 206.

Duel connections are made in view 232 to and between the gate conductor 210 in view 232 by a contact 212 above and a contact 242 below the gate conductor 210. Metal lines 244 and 248 in region 240 correspond in a mirror image relationship with corresponding metal lines 214 and 208. Likewise the contacts 212 and 242 make duel connections from opposing positions relative to the gate conductors 210.

Duel connections are made in view 234 to and between the gate conductor 210 in view 234 by a contact 212 above and a contact 242 below the gate conductor 210. Metal line 244 in region 240 corresponds in a mirror image relationship with corresponding metal lines 214. Likewise the contacts 212 and 242 make duel connections from opposing positions relative to the gate conductor 210.

The duel connections on opposite sides of the device 200 with mirror imaging between top and bottom metal structures is particularly useful in I/O circuitry, clock distribution circuitry, high performance circuitry (HPC) and other circuits that are sensitive to parasitic loss and wire resistance issues. In this way, the mirror image of opposite wiring schemes reduces current density by halving the current through each of the duel connections.

The duel connections on opposite sides of the device 200 also can address issues resulting from large gate structures. Gate conductor 210, e.g., could be activated from top and bottom concurrently to switch a transistor on and off. For a large gate, resistance is large across the gate structure especially at positions that are most distant across the gate structure. By providing two connection points on opposite sides of the gate conductor 210, gate resistance is greatly reduced and better device performance can be achieved.

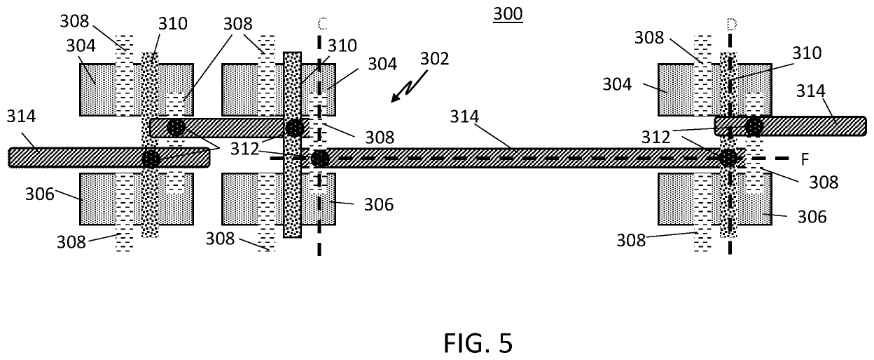

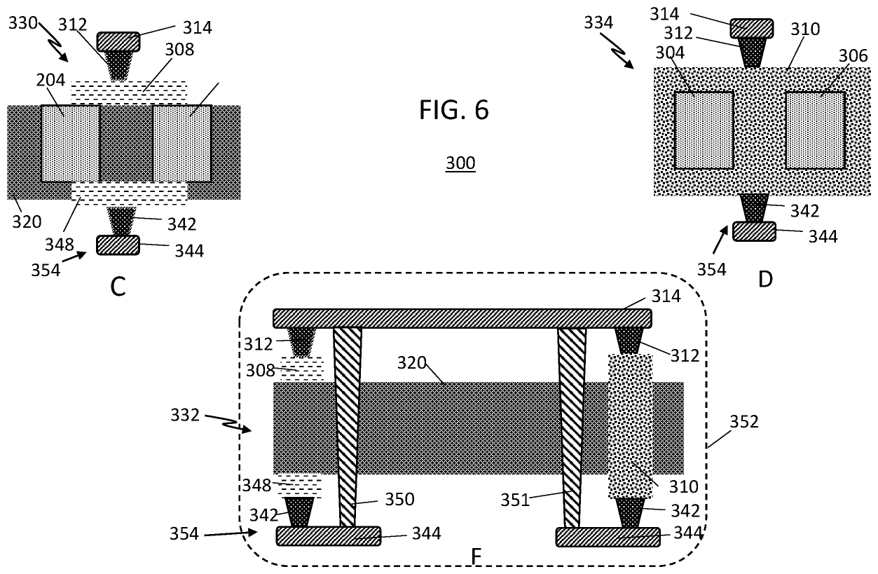

Referring to FIGS. 5 and 6, a top layout view 302 and three partial schematic cross-sectional views 330, 332, 334 are shown for a semiconductor device 300 having dual connections in accordance with embodiments of the present invention. Dielectric materials and layers are omitted to permit viewing of underlying metal structures. The top view 302 shows active regions 304 and 306. In one embodiment, the active regions 304 include p-doped regions, and the active regions 306 include n-doped regions. This can be reversed or all regions can be n-doped or p-doped. The active regions 304 and 306 provide S/D regions that form transistor devices, such as field effect transistors (FETs) as well as channels between the S/D regions. The channels for the devices are located below gate conductors 310. The gate conductors 310 are connected to metal lines 314 through contacts 312. The active regions 304, 306 are connected, where appropriate by metal lines 308. Contacts 312 connect the metal lines 308 to the metal lines 314.

STI regions 320 are depicted in the partial cross-sectional views 330, 332 and 334. View 330 is taken through section line C, view 332 is taken through section line F and view 334 is taken through section line D as shown in top view 302. Duel connections are made in view 330 to and between the active regions 304 and 306 by a contact 312 above and a contact 342 below the active regions 304 and 306. Metal lines 344 and 348 correspond in a mirror image relationship with corresponding metal lines 314 and 308 in view 330. Likewise the contacts 312 and 342 make duel connections from opposing positions relative to the active regions 304 and 306.

Duel connections are made in view 334 to and between the gate conductor 310 by a contact 312 above and a contact 342 below the gate conductor 310. Metal line 344 in region 340 corresponds in a mirror image relationship with corresponding metal lines 314. Likewise, the contacts 312 and 342 make duel connections from opposing positions relative to the gate conductor 310.

Duel connections are made in view 332 to and between the gate conductor 310 by a contact 312 above and a contact 342 below the gate conductor 310. Metal lines 344 and 348 do not correspond in a mirror image relationship with metal lines 314 and 308. Here, modifications have been made to have backside metal structures 354 supplement front side metal structures of view 302. In region 352, frontside metal structures and backside metal structures are not symmetric but still provide a metal balance and duel connections on opposing sides of a central region between the frontside metal structures and the backside metal structures.

Through contacts 350 and 351 are provided through the central region (which includes a substrate of the device 300) to make connections between that frontside metal structures and backside metal structures. In view 332, a through contact 350 connects metal line 314 to metal line 344. The through contacts 350 passes through the substrate and other structures in the central region of the device. In addition to duel connections provided by contacts 312 and 342, through contact 350 provides an additional conductive path across the central region, and reduces resistance for a connection path between the active region 304 and 306 which are connected as depicted in view 330. The added connection of through contact 350 can reduce signal delays and permits an overall less resistive electrical path between electrical nodes.

Through contact 351 is also provided through the central region (which includes a substrate of the device 300) to make connections between that frontside metal structures and backside metal structures. In view 332, through contact 351 connects metal line 314 to metal line 344. The through contact 351 passes through the substrate and other structures in the central region of the device. In addition to duel connections provided by contacts 312 and 342, through contact 351 provides an additional conductive path across the central region connecting two ends of the gate conductor 310. This further reduces gate resistance. The added connection of through contact 351 can reduce signal delays and permits an overall less resistive electrical path. This improves transistor switching performance and reduces signal delays in the gate.

The duel connections on opposite sides of the device 300 are substantially mirror imaged between top and bottom metal structures. While not fully symmetrical, the substantial symmetry still can provide improvements for I/O circuitry, clock distribution circuitry, high performance circuitry (HPC) and other circuits that are sensitive to parasitic loss and wire resistance issues and still provide improvement in electro-migration performance by providing multiple conductive paths.

The duel connections on opposite sides of the device 300 also can address issues resulting from large gate structures. Gate conductor 310, e.g., could be activated from top and bottom concurrently to switch a transistor on and off. The additional connection provided by through contact 351 further ensures that resistivity is decreased especially at opposing positions which are most distant across a gate structure (e.g., gate conductor 310). By providing two connection points on opposite sides of the gate conductor 310 plus a redundant through contact 351 therebetween, gate resistance is reduced and better device performance can be achieved.

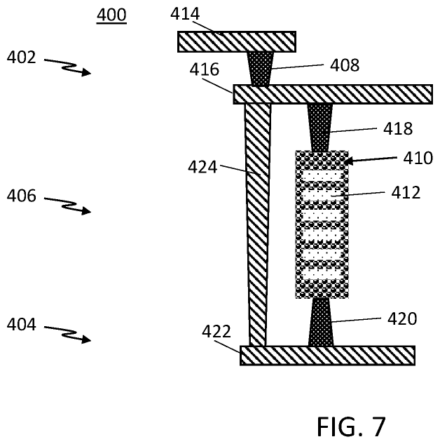

Referring to FIG. 7, a partial schematic cross-sectional view is shown for a semiconductor device 400 having dual connections in accordance with embodiments of the present invention. Dielectric materials and layers are omitted to permit viewing of underlying metal structures. A gate structure 410 includes a nanosheet (NS) structure. Nanosheets include a plurality of layers that are prefabricated and employed to reduce production costs. Nanosheets often include a large number of alternating layers that are processed to form metal gates, such as high dielectric constant metal gate (HKMG) structures. Due to areal constraints on a semiconductor chip, gate structures have grown vertically. As the vertical dimension has increased so has gate resistance.

In one embodiment, duel connections are made to the gate structure 410 by a contact 418 associated with a top side 402 metal structure that includes metal lines 414 and 416 and contact 408, and by a contact 420 associated with a bottom side 404 metal structure that includes metal line 422. A through contact 424 spans across a central region 406 which includes a substrate and other components. Through contact 424 connects a top and bottom of the gate structure 410 by an alternate path. Metal lines 416 and 422 correspond in a mirror image relationship; however, the mirror image is not maintained in this embodiment in higher metal layers (e.g., metal line 414). Instead, the metal lines 414 and contact 408 are aligned with the through contact 424 to provide a more direct connection (e.g., metal line 414, contact 408, metal line 416, through contact 424, metal line 422) between a circuit on the top side 402 through the central region 406 to a circuit on the bottom side 404.

Through contact 424 passes through the substrate and other structures in the central region 406 of the device 400. In addition to duel connections provided by contacts 418 and 420, through contact 424 provides an additional conductive path across the central region 406 connecting two ends of the gate structure 410. This further reduces gate resistance especially for a tall nanosheet gate structure that includes many layers. The added connection of through contact 424 with its direct connection with contact 408 on the top side 402 can further reduce signal/power delays and permit a less resistive electrical path.

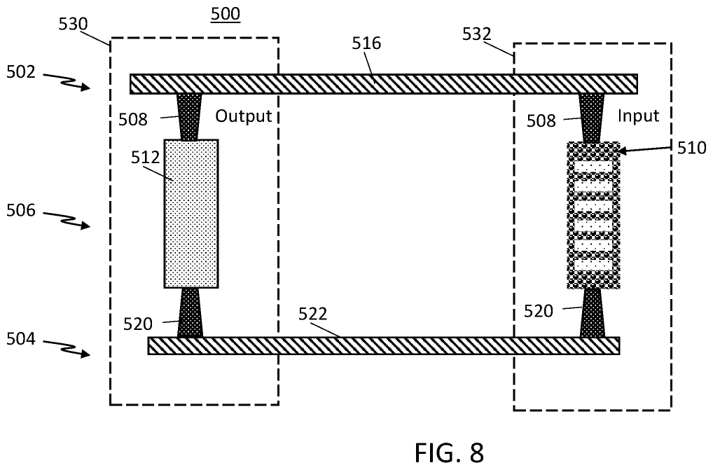

Referring to FIG. 8, a partial schematic cross-sectional view is shown for a semiconductor device 500 having dual connections in accordance with embodiments of the present invention. Dielectric materials and layers are omitted to permit viewing of underlying metal structures. A gate structure 510 can include a nanosheet structure, such as, e.g., a high dielectric constant metal gate (HKMG) structure. Gate structure 510 is included as part of an electrical circuit 532. The electrical circuit 530 can include any useful circuit such as a memory circuit, I/O circuit, etc. In one embodiment, duel connections are made to the gate structure 510 by a contact 508 associated with a top side 502 metal structure that includes metal line 516 and contacts 508, and by a contact 520 associated with a bottom side 504 metal structure that includes metal line 522 and contacts 520.

Duel connections are also provided across a central region 506. Source/drain region 512 is connected to by opposing contacts 508 and 520, which are included as part of an electrical circuit 530. The electrical circuit 530 can include any useful circuit such as a memory circuit, I/O circuit, etc. Circuit 530 and circuit 532 can be connected or wired together using dual connections between components of each circuit. In this way, two sub-circuits 530, 532 can form a single circuit distributed across any of the top side wiring, the bottom side wiring and the central portion of the device 500. In one embodiment, the circuits 530 and 532 are connected with duel connections (e.g., metal lines 516 and 522) to form a single input/output circuit. As shown in FIG. 8, a duel connection path connects different devices within different circuits 530, 532, but each component (e.g., S/D region 512 and gate structure 510) includes a top connection (contact 508) and a bottom connection (contact 520).

Metal lines 516 and 522 correspond in a mirror image relationship; however, components and circuit elements can be connected using both the top side 502 metal structure and the bottom side 504 metal structure to make connections to the same components, to components within a same circuit or to components in different circuits on a chip. The duel connection structure for the herein-described embodiments provides an additional connection opportunity and permits additional flexibility in realizing circuit configurations for performance or functionality. These performance enhancing features can come without cost to chip area or additional processing steps as the additional metal lines can be integrated into existing process of record (POR) sequences.

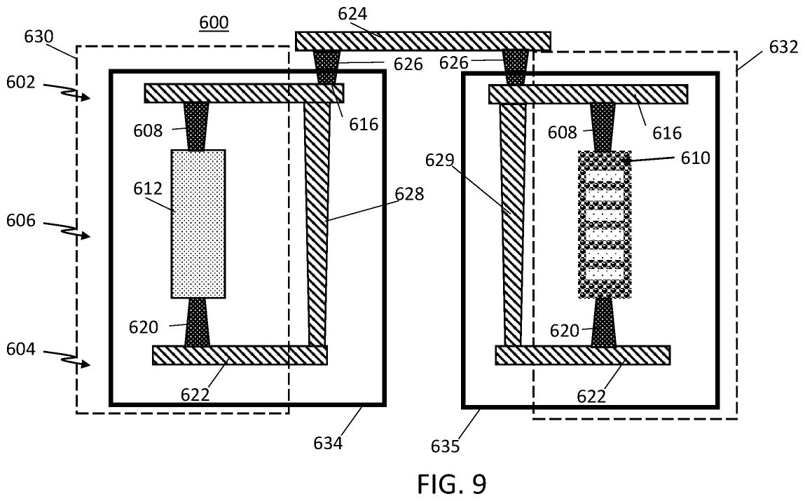

Referring to FIG. 9, a partial schematic cross-sectional view is shown for a semiconductor device 600 having dual connections with additional through contact connections in accordance with embodiments of the present invention. Dielectric materials and layers are omitted to permit viewing of underlying metal structures. In the configuration depicted in FIG. 9, local dual connections 634, 635 are made by employing through contacts 628 and 629, respectively, along with contacts 608 and 620. Duel connections are provided across a central region 606, which includes a semiconductor substrate and other chip components. These local connections are then connected to each other or to other structures using higher level metal structures (e.g., a bridge 624 and contacts 626).

Source/drain region 612 is connected to by opposing contacts 608 and 620, which are included as part of an electrical circuit 630. A gate structure 610 is connected to by opposing contacts 608 and 620, which are included as part of an electrical circuit 632. The electrical circuits 630, 632 can include any useful circuit such as a memory circuit, I/O circuit, etc. Circuit 630 and circuit 632 can be connected or wired together using a bridge 624, which can be positioned on a single side of the central region 606 on a top side 602 in this case. In other embodiments, the bridge 624 can be formed on a bottom side 604, and, in other embodiments, the bridge 624 can be formed on both the top side 602 and the bottom side 604 in a mirror image or non-mirror image relative to the other side.

In one embodiment, the circuits 630 and 632 are connected by the bridge 624, which includes a metal line and contacts 626. The contacts 626 connect to metals lines 616, which in turn connect to contacts 608. Contacts 626 can achieve a performance advantage by being close to a connection point of the contacts 628 and 629. In this way, line resistance can be reduced. Connecting the circuits 630 and 632 can provide a single input/output circuit that is distributed across the device 600 and is located on opposing sides of the central region 606. The duel connection structure provides an additional connection opportunity and permits additional flexibility in realizing circuit configurations for performance or functionality.

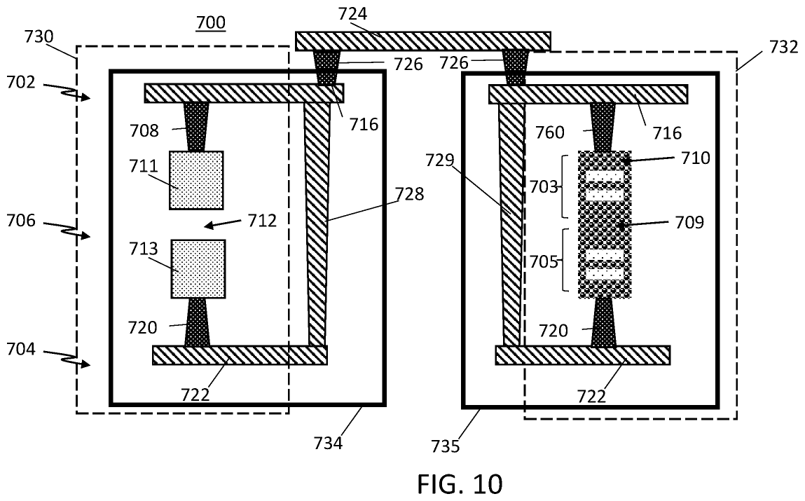

Referring to FIG. 10, a partial cross-sectional view is shown for a semiconductor device 700 having dual connections with additional through contact connections in accordance with embodiments of the present invention. Dielectric materials and layers are omitted to permit viewing of underlying metal structures. In the configuration depicted in FIG. 10, local dual connections 734, 735 are made by employing through contacts 728 and 729, respectively, along with contacts 708 and 720. Duel connections are provided across a central region 706, which includes a semiconductor substrate and other chip components. These local connections are then connected to each other or to other structures using higher level metal structures (e.g., a bridge 724 and contacts 726).

In one embodiment, semiconductor device 700 includes a stacked field effect transistor (FET) device. Stacked FET device includes active regions 711 (e.g., S/D regions) on a top side 702 and active regions 713 (e.g., S/D regions) on a bottom side 704. The top side and bottom side active regions 711, 713 provide S/D regions for operational FETs that are stacked and separated by a distance 712 that includes dielectric. Corresponding active regions 711 and 713 can be connected across a central region using through contact 728. Active regions 711 and 713 can be connected to, respectively, by contacts 708 and 720, which are included as part of an electrical circuit 730. A gate structure 710 is connected to by opposing contacts 708 and 720, which are included as part of an electrical circuit 732. Here, the gate structure 710 includes a portion 703 on the top side 702 and a portion 705 on the bottom side 704, which are separated by a middle dielectric region 709. The portion 703 and portion 705 can be connected by through contact 729. In other embodiments, the portion 703 and portion 705 of the gate structure 710 can be wired independently and function separately from one another.

The electrical circuits 730, 732 can include any useful circuit such as a memory circuit, I/O circuit, etc. Circuit 730 and circuit 732 can be connected or wired together using a bridge 724, which can be positioned on a single side of the central region 706 on the top side 702 in this case. In other embodiments, the bridge 724 can be formed on the bottom side 704, and, in other embodiments, the bridge 724 can be formed on both the top side 702 and the bottom side 704 in a mirror image or non-mirror image relative to the other side.

In one embodiment, the circuits 730 and 732 are connected by the bridge 724, which includes a metal line and contacts 726. The contacts 726 connect to metals lines 716, which in turn connect to contacts 708. Contacts 726 can achieve a performance advantage by being close to a connection point of the contacts 728 and 729. In this way, line resistance can be reduced. Connecting the circuits 730 and 732 can provide a single input/output circuit that is distributed across the device 700 and is located on opposing sides of the central region 706. The duel connection structure provides an additional connection opportunity and permits additional flexibility in realizing circuit configurations for performance or functionality.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper.” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a top side and a bottom side opposite the top side;
a central portion including a semiconductor substrate disposed between the top side and the bottom side; and
a component disposed in the central portion on the semiconductor substrate, the component including a first electrical connection from the top side and a second electrical connection from the bottom side.

2. The semiconductor device as recited in claim 1, wherein the component includes a gate structure and the first electrical connection connects to a top portion of the gate structure and the second electrical connection connects to a bottom portion of the gate structure opposite the top portion.

3. The semiconductor device as recited in claim 1, wherein the top side includes symmetrical metal structures relative to the bottom side.

4. The semiconductor device as recited in claim 1, wherein the first electrical connection connects to the second electrical connection across the central portion by a through contact.

5. The semiconductor device as recited in claim 1, wherein the component includes an active region and the first electrical connection connects to a top portion of the active region and the second electrical connection connects to a bottom portion of the active region opposite the top portion.

6. The semiconductor device as recited in claim 5, wherein the active region includes a source/drain region of a transistor device.

7. The semiconductor device as recited in claim 5, wherein the active region includes a source/drain region of a stacked field effect transistor device.

8. A semiconductor device, comprising:
top side wiring including metal lines and contacts;
bottom side wiring including metal lines and contacts and disposed opposite the top side wiring;
a central portion including a semiconductor substrate disposed between the top side wiring and the bottom side wiring; and
a component formed on the semiconductor substrate and disposed in the central portion; the component including a first electrical connection from the top side wiring and a second electrical connection from the bottom side wiring.

9. The semiconductor device as recited in claim 8, wherein the component includes a gate structure and the first electrical connection connects to a top portion of the gate structure and the second electrical connection connects to a bottom portion of the gate structure opposite the top portion.

10. The semiconductor device as recited in claim 9, wherein the top side wiring and the bottom side wiring include symmetrical metal structures relative to one another.

11. The semiconductor device as recited in claim 8, wherein the first electrical connection connects to the second electrical connection across the central portion by a through contact that traverses the semiconductor substrate.

12. The semiconductor device as recited in claim 8, wherein the component includes an active region and the first electrical connection connects to a top portion of the active region and the second electrical connection connects to a bottom portion of the active region opposite the top portion.

13. The semiconductor device as recited in claim 12, wherein the active region includes a source/drain region of a transistor device.

14. The semiconductor device as recited in claim 12, wherein the active region includes a source/drain region of a stacked field effect transistor device.

15. The semiconductor device as recited in claim 8, wherein the top side wiring mirrors the bottom side wiring relative to the central portion.

16. The semiconductor device as recited in claim 8, wherein the top side wiring mirrors the bottom side wiring in three dimensions.

17. A semiconductor device, comprising:
top side wiring including metal lines and contacts;
bottom side wiring including metal lines and contacts and disposed opposite the top side wiring;
a central portion including a semiconductor substrate disposed between the top side wiring and the bottom side wiring;
a first component formed on the semiconductor substrate and disposed in the central portion, the first component including a first electrical connection from the top side wiring and a second electrical connection from the bottom side wiring;
a second component formed on the semiconductor substrate and disposed in the central portion, the second component including a first electrical connection from the top side wiring and a second electrical connection from the bottom side wiring; and
a bridge connecting the first electrical connection of the first component to the first electrical connection of the second component.

18. The semiconductor device as recited in claim 17, wherein the first component includes a gate structure and the first electrical connection connects to a top portion of the gate structure and the second electrical connection connects to a bottom portion of the gate structure opposite the top portion.

19. The semiconductor device as recited in claim 17, wherein the first electrical connection connects to the second electrical connection across the central portion by a respective through contact that traverses the semiconductor substrate.

20. The semiconductor device as recited in claim 17, wherein the second component includes an active region and the first electrical connection connects to a top portion of the active region and the second electrical connection connects to a bottom portion of the active region opposite the top portion.

21. The semiconductor device as recited in claim 17, wherein the top side wiring mirrors the bottom side wiring relative to the central portion.

22. A semiconductor device, comprising:
top side wiring including metal lines and contacts;
bottom side wiring including metal lines and contacts and disposed opposite the top side wiring;
a central portion including a semiconductor substrate disposed between the top side wiring and the bottom side wiring;
a first circuit disposed in the top side wiring and the bottom side wiring, the first circuit including a first component including a first electrical connection from the top side wiring and a second electrical connection from the bottom side wiring;
a second circuit disposed in the top side wiring and the bottom side wiring, the second circuit including a second component including a first electrical connection from the top side wiring and a second electrical connection from the bottom side wiring; and
a bridge connecting the first circuit to the second circuit to form a single circuit across the top side wiring, bottom side wiring and the central portion, wherein the top side wiring mirrors the bottom side wiring relative to the central portion.

23. The semiconductor device as recited in claim 22, wherein the first component includes a gate structure and the first electrical connection of the first component connects to a top portion of the gate structure and the second electrical connection of the first component connects to a bottom portion of the gate structure opposite the top portion.

24. The semiconductor device as recited in claim 22, wherein the first electrical connection connects to the second electrical connection across the central portion by a respective through contact that traverses the semiconductor substrate.

25. The semiconductor device as recited in claim 22, wherein the second component includes an active region and the first electrical connection of the second component connects to a top portion of the active region and the second electrical connection of the second component connects to a bottom portion of the active region opposite the top portion.
